(19) United States
(12) Patent Application Publication
(10) Pub. No.: US 2025/0183585 A1
(43) Pub. Date: Jun. 5, 2025

(54) SHIELD CONNECTOR

(71) Applicants: AUTONETWORKS TECHNOLOGIES, LTD., Mie (JP); SUMITOMO WIRING SYSTEMS, LTD., Mie (JP); SUMITOMO ELECTRIC INDUSTRIES, LTD., Osaka (JP)

(72) Inventors: Hiroya TANAKA, Mie (JP); Junichi MUKUNO, Mie (JP); Jaeyeon KIM, Mie (JP); Yuta KANEMATSU, Mie (JP); Sunghyun BYUN, Mie (JP)

(21) Appl. No.: 18/845,891

(22) PCT Filed: Mar. 3, 2023
(86) PCT No.: PCT/JP2023/008018

§ 371 Date: Sep. 11, 2024

(30) Foreign Application Priority Data
Mar. 14, 2022 (JP) 2022-039429

(51) Int. Cl. H01R 13/533; H01R 13/6581

(52) U.S. Cl. CPC H01R 13/533; H01R 13/6581

(57) ABSTRACT

A shield connector includes a terminal fitting including a terminal connecting portion to be connected to a mating terminal, an insulating housing for accommodating the terminal fitting, a shield shell for covering an outer surface of the housing, an insulating heat dissipation member having a connecting portion side contact surface to be held in contact with the terminal connecting portion and a shell side contact surface to be held in contact with the shield shell by being exposed through a first opening of the housing, and a spring member for applying a resilient force to a pressure receiving surface of the terminal fitting.

### TECHNICAL FIELD

The present disclosure relates to a shield connector.

### BACKGROUND

Patent Document 1 discloses a shield connector provided with a terminal fitting including a terminal connecting portion to be connected to a mating terminal, a wire connected to a wire connecting portion of the terminal fitting and a shield shell made of metal for covering the wire connecting portion of the terminal fitting and the wire, the wire connecting portion and the shield shell being integrated by an insert-molded insulating resin portion. In this shield connector, the wire connecting portion of the terminal fitting is integrated with the shield shell by being closely covered by the insulating resin portion filled to fill up an air layer in the shield shell by insert molding. Thus, heat generated in an electrically conductive path is quickly transferred from the insulating resin portion to the shield shell made of metal without via the air layer and dissipated, wherefore the heat dissipation of the shield connector can be improved.

### PRIOR ART DOCUMENT

### Patent Document

Patent Document 1: JP 2018-113119 A

### SUMMARY OF THE INVENTION

### Problems to be Solved

In the shield connector described in Patent Document 1, there is a possibility of reducing desired heat dissipation performance if short shots or voids (gaps) occur due to resin fluidity at the time of molding the insulating resin portion. Further, since the insulating resin portion and the shield connector and the terminal fitting made of metal have different linear expansion coefficients, there is also a possibility of reducing heat dissipation performance due to the generation of an air layer (gap) between contact surfaces of the insulating resin portion and the shield connector and the terminal fitting made of metal caused by an ambient temperature change during use. Further, since a part of the terminal fitting to be contacted by the insulating resin portion is the wire connecting portion, there has been also an inherent problem that a distance from the terminal connecting portion where heat is generated most in the electrically conductive path to the shield shell, which is a heat dissipating part, is long and thermal resistance is large.

Accordingly, a shield connector of a novel structure is disclosed which can stably exhibit desired heat dissipation performance in a shorter heat dissipation path by suppressing a reduction in heat dissipation performance due to an ambient temperature change.

### Means to Solve the Problem

The present disclosure is directed to a shield connector with a terminal fitting including a terminal connecting portion to be connected to a mating terminal, an insulating housing for accommodating the terminal fitting, a shield shell for covering an outer surface of the housing, an insulating heat dissipation member having a connecting portion side contact surface to be held in contact with the terminal connecting portion and a shell side contact surface to be held in contact with the shield shell by being exposed through a first opening of the housing, and a spring member for applying a resilient force to a pressure receiving surface of the terminal fitting, the terminal connecting portion being pressed against the connecting portion side contact surface of the heat dissipation member and the shell side contact surface of the heat dissipation member being pressed against the shield shell by the resilient force of the spring member applied to the pressure receiving surface of the terminal fitting.

### Effect of the Invention

According to a shield connector of the present disclosure, desired heat dissipation performance can be stably exhibited in a shorter heat dissipation path by suppressing a reduction in heat dissipation performance due to an ambient temperature change.

### BRIEF DESCRIPTION OF THE DRAWINGS

FIG. 1 is a perspective view of a shield connector according to a first embodiment.

FIG. 2 is a plan view of the shield connector shown in FIG. 1.

FIG. 3 is a side view of the shield connector shown in FIG. 1.

FIG. 4 is a section along IV-IV in FIG. 3.

FIG. 5 is a section along V-V in FIG. 4.

FIG. 6 is an exploded perspective view of the shield connector shown in FIG. 1.

FIG. 7 is a perspective view showing a housing constituting the shield connector shown in FIG. 1 when viewed from above.

FIG. 8 is a perspective view showing the housing shown in FIG. 7 when viewed from below.

FIG. 9 is a perspective view showing an insulating cover constituting the shield connector shown in FIG. 1.

FIG. 10 is a perspective view showing a terminal side assembly constituting the shield connector shown in FIG. 1.

FIG. 11 is a perspective view showing a spring member in the shield connector shown in FIG. 1 in a single state before being assembled.

FIG. 12 is a section, corresponding to FIG. 4, showing a state where mating terminals are connected to the shield connector shown in FIG. 1.

FIG. 13 is a longitudinal section, corresponding to FIG. 4, showing a shield connector according to a second embodiment.

FIG. 14 is a section, corresponding to FIG. 5, along XIV-XIV in FIG. 13.

FIG. 15 is a perspective view showing a spring member constituting the shield connector shown in FIG. 13.

### DETAILED DESCRIPTION TO EXECUTE THE INVENTION

### Description of Embodiments of Present Disclosure

First, embodiments of the present disclosure are listed and described.
(1) The shield connector of the present disclosure is provided with a terminal fitting including a terminal connecting portion to be connected to a mating terminal, an insulating housing for accommodating the terminal fitting, a shield shell for covering an outer surface of the housing, an insulating heat dissipation member having a connecting portion side contact surface to be held in contact with the terminal connecting portion and a shell side contact surface to be held in contact with the shield shell by being exposed through a first opening of the housing, and a spring member for applying a resilient force to a pressure receiving surface of the terminal fitting, the terminal connecting portion being pressed against the connecting portion side contact surface of the heat dissipation member and the shell side contact surface of the heat dissipation member being pressed against the shield shell by the resilient force of the spring member applied to the pressure receiving surface of the terminal fitting.

According to the shield connector of the present disclosure, the insulating heat dissipation member having the connecting portion side contact surface to be held in contact with the terminal connecting portion of the terminal fitting and the shell side contact surface to be held in contact with the shield shell by being exposed through the first opening of the housing is adopted instead of the insulating resin portion molded to fill a gap between the shield shell and the terminal fitting in the conventional structure. That is, since the separate heat dissipation member is used instead of the molded insulating resin portion in a heat dissipation path, it is possible to reduce a possibility of reducing desired heat dissipation performance due to possible occurrence of short shots and voids during molding. Further, the terminal connecting portion is pressed against the connecting portion side contact surface of the heat dissipation member and the shell side contact surface of the heat dissipation member is pressed against the shield shell by applying the resilient force of the separate spring member to the pressure receiving surface of the terminal fitting and pressing the pressure receiving surface. In this way, even if an ambient temperature changes during use, the heat dissipation member interposed between the terminal connecting portion and the shield shell can be stably held in a state in contact with the terminal connecting portion and the shield shell utilizing the resilient force of the spring member. In addition, since a part of the terminal fitting to be contacted by the heat dissipation member is the terminal connecting portion, the terminal connecting portion where heat is generated most in an electrically conductive path can be directly brought into contact with the shield shell via the heat dissipation member. As a result, the heat dissipation path can be shortened and desired heat dissipation performance can be stably exhibited as compared to the conventional structure.

Note that an arbitrary shape can be adopted for the spring member if the spring member can apply a resilient force to the pressure receiving surface of the terminal fitting. Similarly, an arbitrary shape can be adopted for the terminal fitting if the terminal fitting includes the terminal connecting portion having the pressure receiving surface for receiving the resilient force of the spring member and the connecting portion side contact surface to be pressed against the heat dissipation member by the resilient force of the spring member transferred from the pressure receiving surface. Further, an arbitrary shape can be adopted for the heat dissipation member if the heat dissipation member can press the shell side contact surface of the heat dissipation member against the shield shell by the resilient force of the spring member transferred to the connecting portion side contact surface.
(2) Preferably, the terminal connecting portion of the terminal fitting has a rectangular tube shape, a mating terminal arrangement portion is formed inside the terminal connecting portion, the mating terminal being inserted into the mating terminal arrangement portion, and the pressure receiving surface is formed by one of a pair of facing wall portions of the terminal connecting portion, a contact surface is formed by the other of the pair of facing wall portions, and the contact surface is pressed into contact with the connecting portion side contact surface of the heat dissipation member. Since the terminal connecting portion of the terminal fitting has the rectangular tube shape, the mating terminal arrangement portion can be provided inside the terminal connecting portion and a risk that the mating terminal arrangement portion and the mating terminal interfere with the spring member can be eliminated or reduced. Particularly, if a resilient contact piece or the like to be brought into resilient contact with the mating terminal projects in the mating terminal arrangement portion, the deformation of the resilient contact piece is hindered and a desired contact state with the mating terminal can be advantageously maintained. Moreover, since the pressure receiving surface, to which the resilient force of the spring member is applied, and the contact surface to be held in contact with the heat dissipation member are formed, using the pair of facing wall portions of the terminal connecting portion having the rectangular tube shape, the resilient force of the spring member can be reliably received and the terminal connecting portion can be pressed against the connecting portion side contact surface of the heat dissipation member while having a wide contact area. As a result, more stable heat dissipation from the terminal connecting portion to the shield shell can be realized.
(3) Preferably, the housing includes a second opening for exposing the pressure receiving surface of the terminal fitting and an insulating cover to be assembled with the second opening to contact the pressure receiving surface, and the spring member applies the resilient force to the pressure receiving surface via the insulating cover. Since the insulating cover to be held in contact with the pressure receiving surface is assembled with the second opening of the housing for exposing the pressure receiving surface of the terminal fitting and the resilient force of the spring member is applied to the pressure receiving surface via the insulating cover, the resilient force of the spring member can be applied to the pressure receiving surface while the insulation of the terminal fitting is stably ensured. Moreover, the insulating cover is assembled with the second opening, for example, by known locking engagement or the like. Therefore, the assembly type shield connector configured by assembling the separate terminal fitting and spring member with the housing can be provided, and heat dissipation performance can be more reliably achieved as compared to the conventional resin molded type shield connector.
(4) Preferably, the insulating cover includes a flat plate-like cover body for covering the second opening and a plurality of contact ribs projecting from the cover body toward the pressure receiving surface to be held in contact with the pressure receiving surface. Since the insulating cover is composed of the flat plate-like cover body for covering the second opening and the plurality of contact ribs projecting from the cover body, deformation due to resin sinks and the like is reduced and the second opening can be stably covered as compared to the case where the insulating cover is entirely thickly molded with a resin. Moreover, since the plurality of contact ribs contact the pressure receiving surface, the resilient force of the spring member applied to the insulating cover can be applied to the plurality of contact ribs in a concentrated manner and the resilient force of the spring member can be more stably applied to the pressure receiving surface of the terminal fitting while the rigidity of the insulating cover is ensured. Note that an arbitrary shape can be adopted for the plurality of contact ribs if the resilient force of the spring member can be stably applied to the pressure receiving surface of the terminal fitting.
(5) Preferably, the insulating cover includes an engaging rib for hindering the terminal fitting from coming out from the housing by being engaged with the terminal connecting portion. Since the terminal fitting is hindered from coming out from the housing by the engagement of the engaging rib provided on the insulating cover with the terminal connecting portion, an assembled state of the shield connector can be stably maintained with a small number of components.
(6) Preferably, the housing includes a holding member for holding the heat dissipation member by being assembled with the first opening. Since the exposed heat dissipation member capable of contacting the shield shell via the first opening of the housing can be held by the holding member assembled with the first opening, the heat dissipation member can be more stably held and the heat dissipation performance of the shield connector can be stably kept. Moreover, the holding member is assembled with the first opening of the housing, for example, by known locking engagement or the like. Therefore, the assembly type shield connector configured by assembling the separate terminal fitting and heat dissipation member with the housing can be provided, and an improvement in heat dissipation performance can be more reliably achieved as compared to the conventional resin molded type shield connector.
(7) Preferably, a pair of the housings for respectively accommodating a pair of the terminal fittings include each the heat dissipation member and are covered by the single shield shell with the respective pressure receiving surfaces arranged to face each other, the single spring member is arranged between the pair of housings, and the resilient force of the spring member is applied to the pressure receiving surface of each of the pair of terminal fittings, each terminal connecting portion is pressed against the connecting portion side contact surface of each heat dissipation member, and the shell side contact surface of each heat dissipation member is pressed against the shield shell.

Since the resilient force of the single spring member can be applied to the pressure receiving surfaces of the pair of terminal fittings covered by the single shield shell, the compact bipolar shield connector can be provided with a small number of components by commonly using the spring member. Further, the pair of terminal fittings are arranged with the pressure receiving surfaces facing each other, and the respective pressure receiving surfaces are pressed toward the heat dissipation members and the shield shell arranged on mutually opposite sides by the single spring member arranged between the pressure receiving surfaces. Therefore, forces for pressing the two terminal fittings against the heat dissipation members can be made uniform by the principle of action and reaction and a variation of heat dissipation performance can be suppressed.
(8) Preferably, the shield shell includes an accommodating portion for accommodating the spring member. Since the shield shell is provided with the accommodating portion for accommodating the spring member, the housing to be covered by the shield shell can be reduced in size, utilizing the shield shell. As a result, a size reduction of the entire shield connector can be advantageously realized.
(9) Preferably, an insulating cap is provided which is assembled with the shield shell while covering the accommodating portion of the shield shell, and the insulating cap integrally includes a mating terminal insertion hole and a spring member cover portion. It can be realized with a small number of components to hinder the separation of the spring member from the accommodating portion and provide the mating terminal insertion hole, utilizing the insulating cap to be assembled with the shield shell.

### Details of Embodiments of Present Disclosure

Specific examples of a shield connector of the present disclosure are described below with reference to the drawings. Note that the present disclosure is not limited to these illustrations, but is represented by claims and intended to include all changes in the scope of claims and in the meaning and scope of equivalents.

### First Embodiment

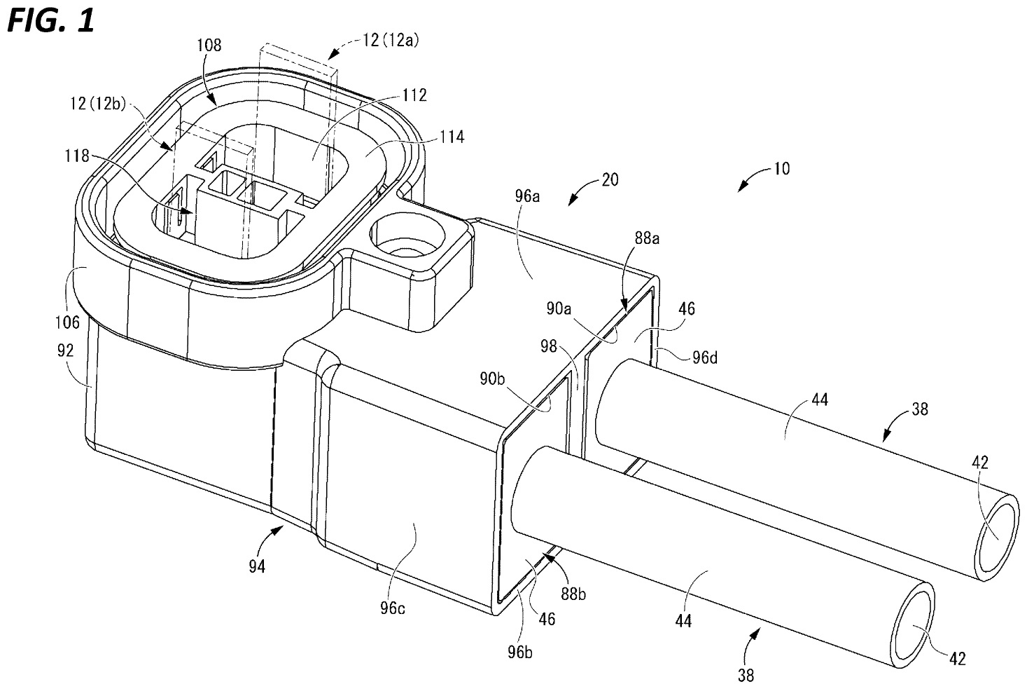

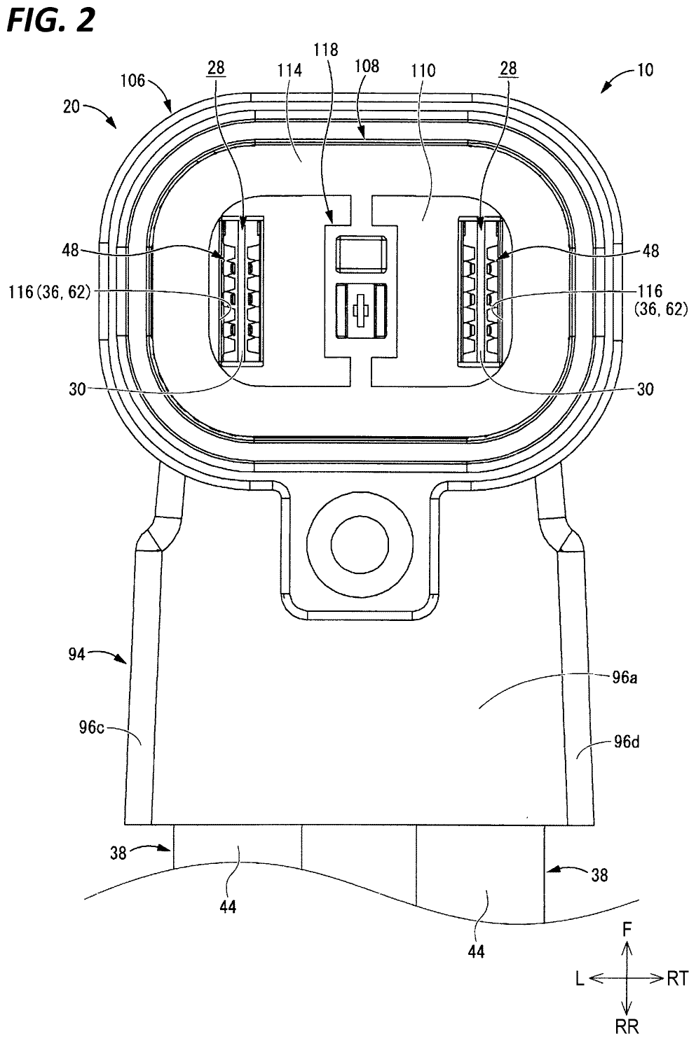

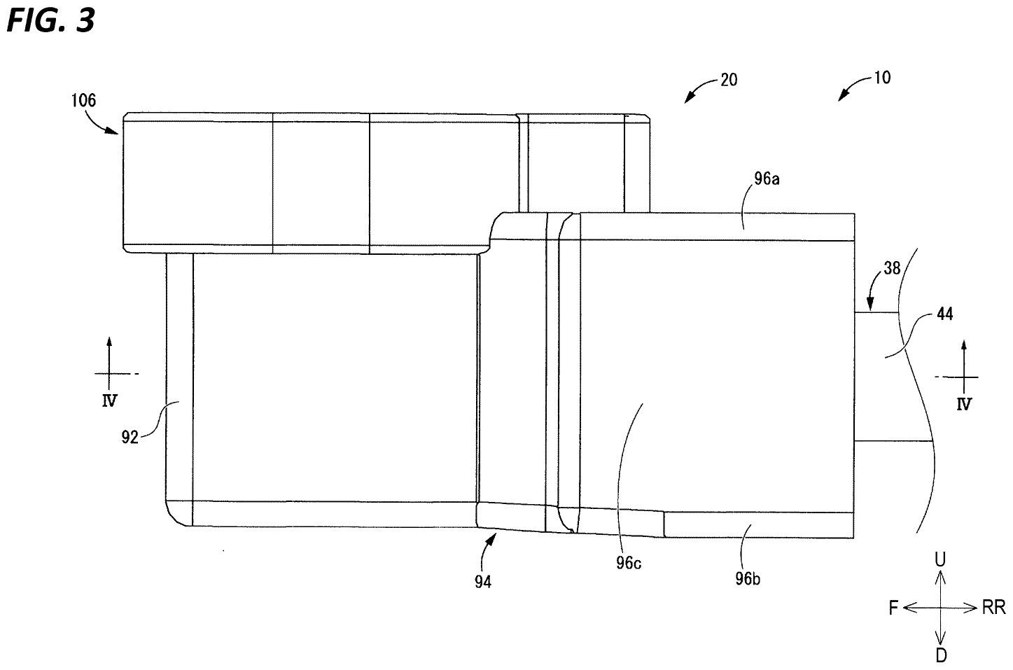

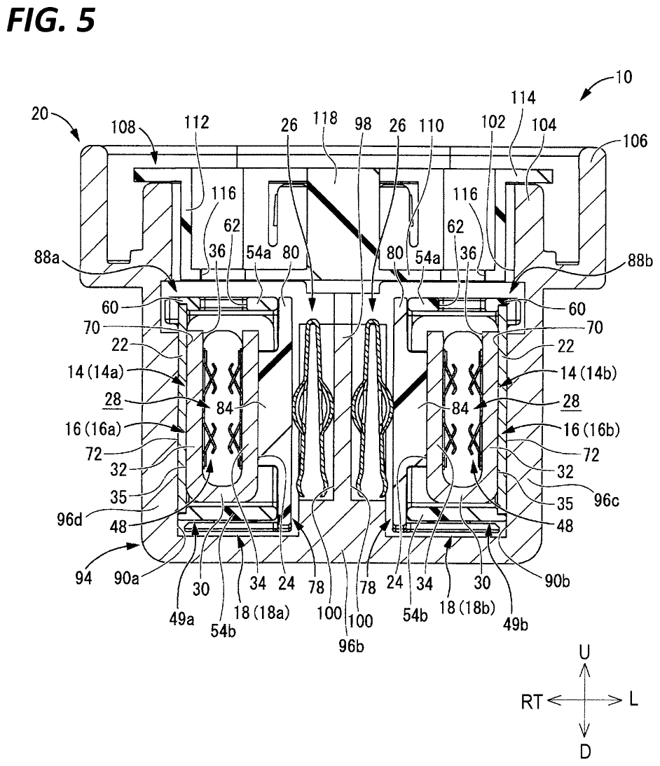

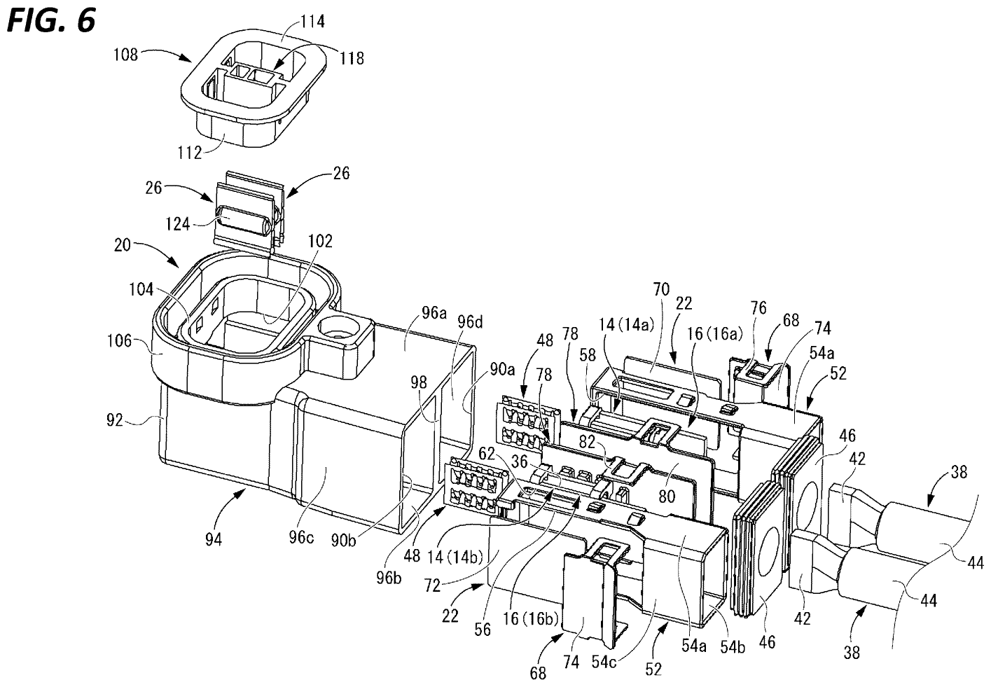

Hereinafter, a shield connector 10 of a first embodiment of the present disclosure is described with reference to FIGS. 1 to 12. This shield connector 10 is, for example, applied to an electric vehicle or a hybrid vehicle, and used in a large current region of a high-voltage connector from a PCU (power control unit) to a battery. Note that the shield connector 10 can be arranged in an arbitrary orientation, but an upper side is an upper side in FIG. 3, a lower side is a lower side in FIG. 3, a front side is a left side in FIG. 3, a rear side is a right side in FIG. 3, a left side is a left side in FIG. 2 and a right side is a right side in FIG. 2 in the following description. Further, for a plurality of identical members, only some members may be denoted by a reference sign and the other members may not be denoted by the reference sign.

### (Shield Connector 10)

The shield connector 10 of the first embodiment is provided with terminal fittings 16 each including a terminal connecting portion 14 to be connected to a mating terminal 12, insulating housings 18 for accommodating the terminal fittings 16, a shield shell 20 for covering the outer surfaces of the housings 18, insulating heat dissipation members 22 and spring members 26 for applying resilient forces to pressure receiving surfaces 24 of the terminal fittings 16. Particularly, in the first embodiment, a pair of the terminal connecting portions 14a, 14b are provided side by side in a lateral direction, and the shield connector 10 includes a pair of the terminal fittings 16a, 16b respectively including the terminal connecting portions 14a, 14b. Further, the shield connector 10 includes a pair of the housings 18a, 18b for respectively accommodating the terminal fittings 16a, 16b.

### (Mating Terminals 12)

The shape of the mating terminal 12 is not limited, but in the form of a substantially flat tab in the first embodiment. Note that, in the first embodiment, a mating terminal arrangement portion 28 is provided inside the terminal connecting portion 14 as described later and the mating terminal 12 is inserted into a mating terminal insertion hole 62 provided in the housing 18. The mating terminal 12 arranged in the mating terminal arrangement portion 28 and the terminal connecting portion 14 of the terminal fitting 16 accommodated in the housing 18 contact and are conductively connected. That is, in the first embodiment, the mating terminal 12 is a male terminal and the terminal connecting portion 14 is a female terminal. Particularly, in the first embodiment, the pair of terminal connecting portions 14a, 14b are provided, and the mating terminals 12a, 12b are respectively inserted into these terminal connecting portions 14a, 14b.

### (Terminal Fittings 16)

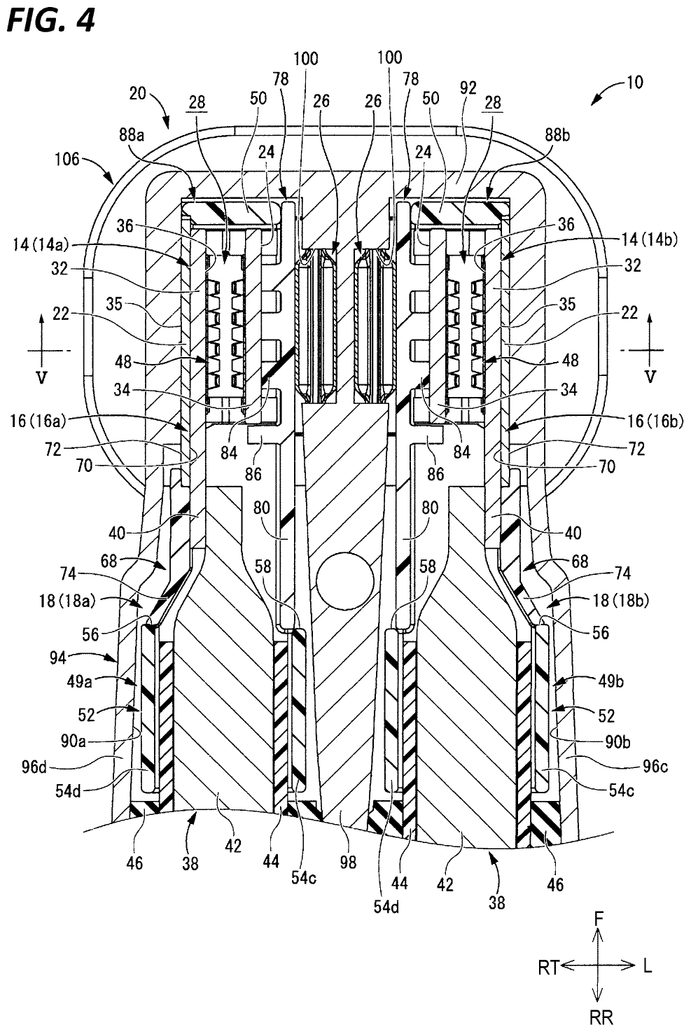

In the first embodiment, the pair of terminal fittings 16a, 16b are provided side by side in the lateral direction. Since these are bilaterally symmetrically shaped, the shape of one (right) terminal fitting 16a is described. As also shown in FIGS. 4 to 6, the terminal connecting portion 14a in the terminal fitting 16a has a substantially rectangular tube shape extending in a front-rear direction and is open on both sides in the front-rear direction in the shield connector 10. That is, the terminal connecting portion 14a includes a lower wall portion 30 constituting a wall portion on a lower side and a pair of facing wall portions projecting upward from both lateral sides of the lower wall portion 30 in an assembled state of the shield connector 10. Note that, in the right terminal fitting 16a, out of the pair of terminal fittings 16a, 16b, a wall portion on a lateral outer side (right side) is an outer wall portion 32, which is one of the pair of facing wall portions, and a wall portion on a lateral inner side (left side) is an inner wall portion 34, out of the pair of facing wall portions. Therefore, a wall portion on the left side is an outer wall portion 32 and a wall portion on a right side is an inner wall portion 34 in the left terminal fitting 16b. As described later, the outer surface of each outer wall portion 32 is a contact surface 35 to be held in contact with a connecting portion side contact surface 70 in each heat dissipation member 22.

Upper end parts of these outer and inner wall portions 32, 34 are coupled in both end parts in the front-rear direction, thereby configuring the terminal connecting portion 14 having the substantially rectangular tube shape. Further, the outer and inner wall portions 32, 34 are not coupled in an intermediate part in the front-rear direction of an upper end part of the terminal connecting portion 14, thereby providing an upper opening 36 open upward. As a result, the mating terminal arrangement portion 28, which is an internal space of the terminal connecting portion 14, and an outside space communicate with each other through the upper opening 36. Note that, as described later, the outer surface (the left end surface of the inner wall portion 34 in the right terminal fitting 16a, the right end surface of the inner wall portion 34 in the left terminal fitting 16b) of the inner wall portion 34 is the aforementioned pressure receiving surface 24, to which a resilient force is applied from the spring member 26.

Such a terminal fitting 16a is formed, for example, by bending a metal flat plate having a predetermined shape into the above shape, and the respective upper end parts of the outer and inner wall portions 32, 34 can be coupled by crimping. Further, in the terminal fitting 16a, the outer wall portion 32 extends further rearward than the inner wall portion 34, and a wire 38 is fixed and connected to a rear end part of the outer wall portion 32 extending further rearward than the inner wall portion 34. That is, the rear end part of the outer wall portion 32 is a wire connecting portion 40, and the terminal connecting portion 14 is provided in a front part and the rear end part serves as the wire connecting portion 40 in the terminal fitting 16a.

The wire 38 is a coated wire, and an insulation coating 44 made of synthetic resin is externally fit to a core wire 42. The insulation coating 44 is stripped in a tip part of the wire 38 to expose the core wire 42, and the wire 38 and the terminal fitting 16a are conductively connected by fixing the exposed core wire 42 to the rear end part (wire connecting portion 40) of the terminal fitting 16a by crimping, welding or the like. Note that an annular waterproof rubber 46 having a substantially rectangular outer shape is externally mounted on a part of the wire 38 behind the exposed core wire 42.

In each terminal connecting portion 14a, 14b, terminal spring portions 48 are provided on the facing inner surfaces of the outer and inner wall portions 32, 34. The terminal spring portions 48 are substantially in the form of rectangular plates as a whole, made of metal good in electrical conductivity and fixed to the respective inner surfaces of the outer and inner wall portions 32, 34. In the terminal spring portion 48, parts raised into a substantially chevron shape project laterally inward, i.e. toward the inside of the mating terminal arrangement portion 28. A plurality of the parts raised into the substantially chevron shape are provided and aligned and arranged in a vertical direction and the front-rear direction. When the mating terminal 12 is inserted and arranged in the mating terminal arrangement portion 28 as described later, the substantially chevron-shaped projecting parts of the terminal spring portions 48 are pressed by the mating terminal 12 and resiliently deformed to reduce a projecting height.

### (Housings 18)

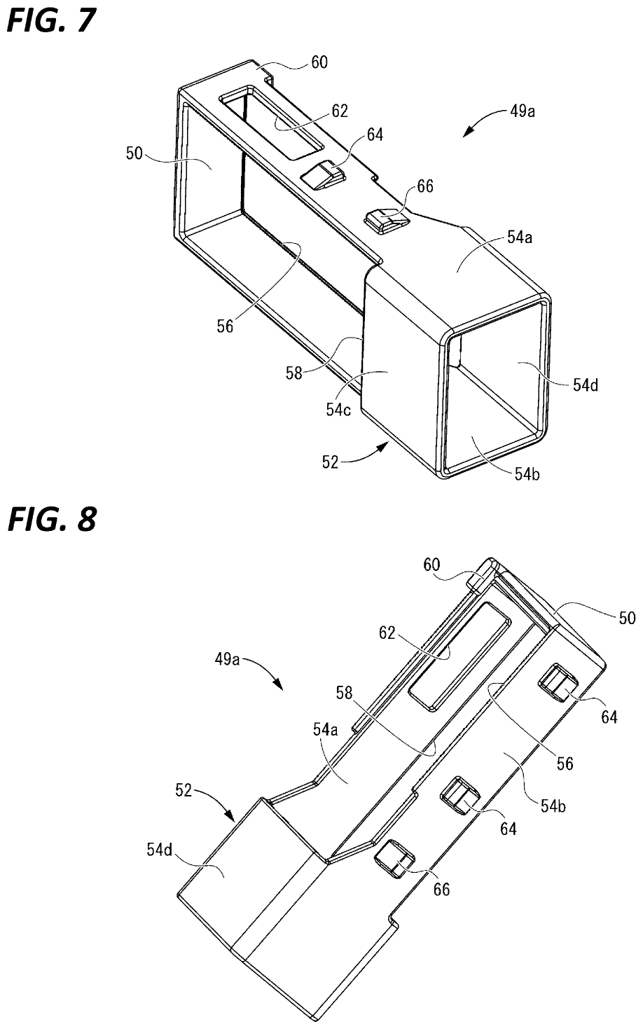

In the first embodiment, the pair of housings 18a, 18b are provided side by side in the lateral direction. Particularly, in the first embodiment, each housing 18a, 18b includes a housing body 49a, 49b, a holding member 68 to be assembled with a first opening 56 to be described later and an insulating cover 78 to be assembled with a second opening 58. Since these housings are bilaterally symmetrically shaped, the shape of one (right) housing 18a is described. As also shown in FIGS. 7 and 8, the housing body 49a has a substantially bottomed tube shape open rearward as a whole and made of insulating synthetic resin. Note that, although a method for forming the housing body 49a is not limited, the housing body 49a is molded and formed separately from the shield shell 20, the holding member 68 and the insulating cover 78, each of which is assembled with the housing body 49a later.

The housing body 49a is provided with a substantially rectangular front wall portion 50 corresponding to a bottom wall in a front end part and a substantially tubular peripheral wall portion 52 projecting rearward from a peripheral edge part on four sides of the front wall portion 50. Accordingly, the peripheral wall portion 52 includes an upper wall portion 54a on an upper side, a lower wall portion 54b on a lower side and left and right wall portions 54c, 54d on both left and right sides. The outer shape of the peripheral wall portion 52 varies in the front-rear direction, and a front part of the peripheral wall portion 52 has a substantially rectangular shape having a vertical dimension larger than a lateral dimension. Further, a rear part of the peripheral wall portion 52 has a larger lateral dimension than the front part, and the lateral dimension and a vertical dimension are substantially equal or the vertical dimension is slightly larger than the lateral dimension. In this way, the rear part of the peripheral wall portion 52 has a substantially square outer shape. That is, an internal space of the housing body 49a is larger in the rear part than in the front part.

The right wall portion 54d is provided with the first opening 56 penetrating in a thickness direction (lateral direction) of the right wall portion 54d for exposing the heat dissipation member 22 from the housing body 49a when the heat dissipation member 22 to be described later is assembled with the housing body 49a. The first opening 56 is provided from a front end part of the right wall portion 54d to a part where the lateral dimension is made larger in the rear part than in the front part, and the internal space of the housing body 49a and an outside space communicate with each other through the first opening 56.

The left wall portion 54c is provided with the second opening 58 penetrating in a thickness direction (lateral direction) of the left wall portion 54c for exposing the pressure receiving surface 24 of the terminal fitting 16a from the housing body 49a when the terminal connecting portion 14a (terminal fitting 16a) to be described later is assembled with the housing body 49a. The second opening 58 is provided from a front end part of the left wall portion 54c to a part where the lateral dimension is made larger in the rear part than in the front part, and the internal space of the housing body 49a and the outside space communicate with each other through the second opening 58.

Note that since the right and left housing bodies 49a, 49b are bilaterally symmetrically shaped, the first opening 56 is provided in the left wall portion 54c and the second opening 58 is provided in the right wall portion 54d in the left housing body 49b. Further, by providing these first and second openings 56, 58 in the housing body 49a, the housing body 49a is shaped such that the upper and lower wall portions 54a, 54b are coupled by the left and right wall portions 54c, 54d only in the rear part.

Further, a positioning protrusion 60 projecting rightward is provided in a front end part of the upper wall portion 54a. Further, the substantially rectangular mating terminal insertion hole 62 penetrating in a thickness direction (vertical direction) is provided in a front part of the upper wall portion 54a. In the upper wall portion 54a, an insulating cover engaging protrusion 64 for assembling the insulating cover 78 to be described later and a holding member engaging protrusion 66 for assembling the holding member 68 are provided apart from each other in the front-rear direction in a part of the upper wall portion 54a behind the mating terminal insertion hole 62. Further, in the lower wall portion 54b, two insulating cover engaging protrusions 64 and one holding member engaging protrusion 66 are provided apart from each other in the front-rear direction and each insulating cover engaging protrusion 64 is located in front of the holding member engaging protrusion 66.

### (Heat Dissipation Members 22)

The shape and material of the heat dissipation member 22 are not limited if the heat dissipation member has an insulating property, but the heat dissipation member 22 has a substantially flat plate shape in this embodiment. Further, the heat dissipation member 22 only has to have a larger thermal conductivity than air, but is preferably excellent in thermal conductivity. In this embodiment, the heat dissipation member 22 is made of ceramic. This heat dissipation member 22 is assembled to cover the first opening 56 in each housing body 49a, 49b, and the heat dissipation member 22 is fixed to each housing body 49a, 49b by assembling the holding member 68 for holding the heat dissipation member 22 with each housing body 49a, 49b from the outside of the heat dissipation member 22.

When the shield connector 10 is assembled, one surface (inner surface) in a plate thickness direction of each heat dissipation member 22 contacts the corresponding terminal connecting portion 14a, 14b and constitutes the connecting portion side contact surface 70. Further, the other surface (outer surface) in the plate thickness direction of each heat dissipation member 22 is exposed on the outer surface of each housing body 49a, 49b through the first opening 56 of each housing body 49a, 49b and contacts the shield shell 20 covering the outer surface of each housing body 49a, 49b. That is, a shell side contact surface 72 is constituted by the other surface in the plate thickness direction of the heat dissipation member 22.

### (Holding Member 68)

The holding member 68 covers a rear end part of each first opening 56 by being assembled with a rear end part of each first opening 56 in each housing body 49a 49b. That is, each holding member 68 includes a substantially plate-like holding member body 74 corresponding to the shape of the first opening 56. Engaging frame bodies 76 projecting toward each assembled housing body 49a, 49b to be assembled are provided in both vertical end parts of each holding member body 74, and engaged with the respective holding member engaging protrusions 66 provided on each housing body 49a, 49b. By assembling the holding member 68 with each housing body 49a, 49b, each heat dissipation member 22 is held from outside by a front end part of each holding member 68 and each heat dissipation member 22 covers each first opening 56.

### (Insulating Cover 78)

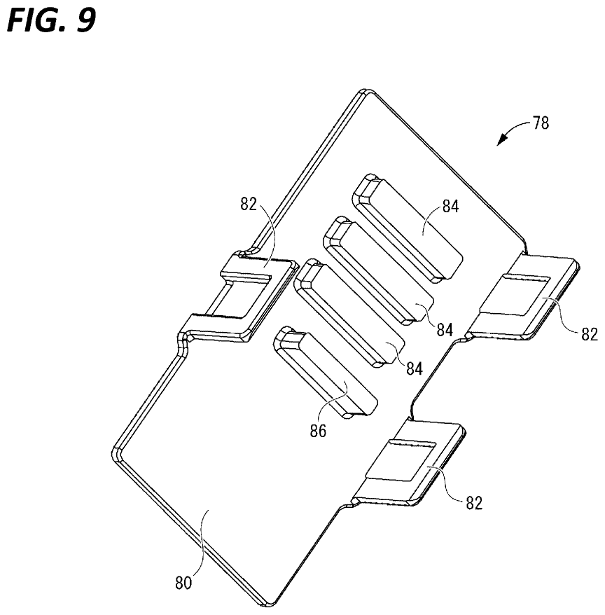

The insulating cover 78 is assembled with the second opening 58 in each housing body 49a, 49b. As also shown in FIG. 9 and the like, the insulating cover 78 includes a flat plate-like cover body 80 of a size capable of covering the second opening 58. Engaging frame bodies 82 projecting toward each assembled housing body 49a, 49b are provided on both vertical end parts of each cover body 80. In the first embodiment, one engaging frame body 82 is provided on the upper end part of each cover body 80 and two engaging frame bodies 82 are provided apart from each other in the front-rear direction on the lower end part of each cover body 80 to correspond to the respective insulating cover engaging protrusions 64 provided on each housing body 49a, 49b. By engaging these engaging frame bodies 82 with the respective insulating cover engaging protrusions 64, the insulating cover 78 is assembled with each housing body 49a, 49b while covering the second opening 58 in each housing body 49a, 49b.

The cover body 80 in each insulating cover 78 is provided with contact ribs 84 and an engaging rib 86 projecting inwardly of each housing body 49a, 49b in a state assembled with the second opening 58 in each housing body 49a, 49b.

The contact ribs 84 project toward the pressure receiving surface 24 of each terminal connecting portion 14a, 14b (each terminal fitting 16a, 16b) accommodated inside each housing body 49a, 49b in the assembled state of the shield connector 10. When each terminal connecting portion 14a, 14b (each terminal fitting 16a, 16b) is assembled with each housing 18a, 18b as described later, the projecting tips of the respective contact ribs 84 and the pressure receiving surface 24 contact each other. In the first embodiment, three contact ribs 84 are provided in each cover body 80 and provided apart from each other in the front-rear direction. By bringing the respective contact ribs 84 in each insulating cover 78 into contact with the pressure receiving surface 24 in this way, the spring member 26 applies a resilient force to the pressure receiving surface 24 via each insulating cover 78 when the resilient force of each spring member 26 acts as described later.

The engaging rib 86 is located behind the inner wall portion 34 constituting each terminal connecting portion 14a, 14b and provided behind the respective contact ribs 84 in each cover body 80 in the assembled state of the shield connector 10. The engaging rib 86 has a larger projecting height from the cover body 80 than the respective contact ribs 84, and is in contact with or slightly separated from the rear end surface of the inner wall portion 34 constituting each terminal connecting portion 14a, 14b in the assembled state of the shield connector 10. In this way, also when an external force in a pull-out direction is applied to the wire 38 from each housing 18a, 18b in the assembled state of the shield connector 10, the engaging rib 86 contacts and is engaged with the inner wall portion 34, whereby each terminal fitting 16a, 16b is prevented from coming out from each housing 18a, 18b.

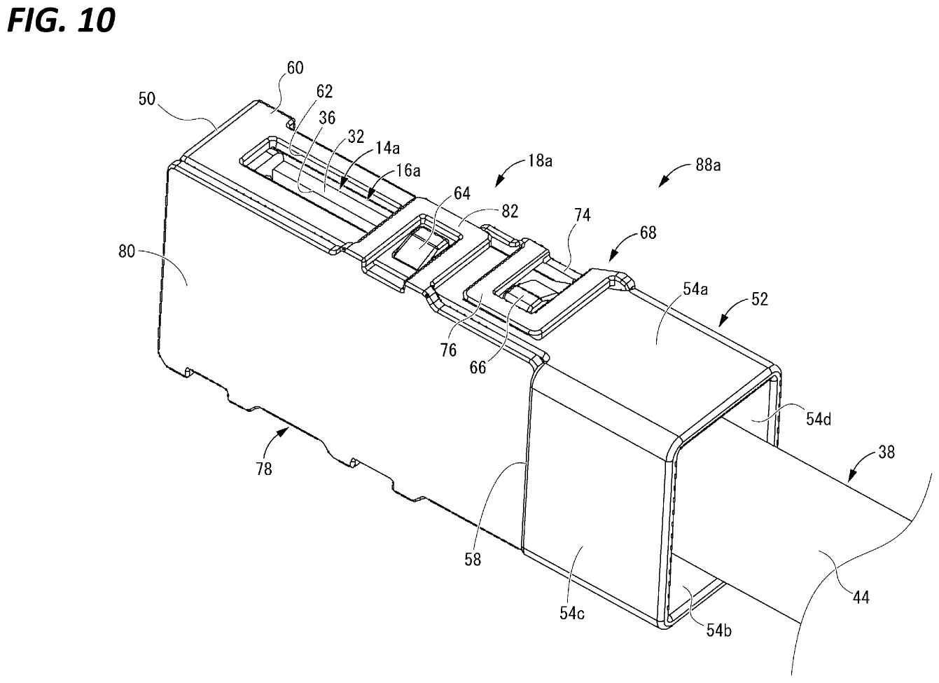

Then, the terminal fitting 16a fixed to the wire 38 at the wire connecting portion 40 is inserted into the housing body 49a through a rear opening of the housing body 49a and the heat dissipation member 22 is overlapped on the outer wall portion 32 in the terminal fitting 16a, and the holding member 68 and the insulating cover 78 are fixed to the first and second openings 56, 58 of the housing body 49a, whereby one (right) terminal side assembly 88a is configured as shown in FIG. 10. Similarly, the other (left) terminal side assembly 88b is configured bilaterally symmetrically with the one terminal side assembly 88a, and this pair of terminal side assemblies 88a, 88b are assembled with the common shield shell 20.

### (Shield Shell 20)

The shield shell 20 is made of metal excellent in heat dissipation. The shield shell 20 is provided with a pair of accommodating tube portions 90a, 90b, into which the respective terminal side assemblies 88a, 88b are inserted and accommodated, and this pair of accommodating tube portions 90a, 90b are arranged side by side in the lateral direction. That is, the shield shell 20 has a substantially bottomed tube shape open rearward as a whole and includes a substantially rectangular front end wall portion 92 and a tubular wall portion 94 projecting rearward from a peripheral edge part on four sides of the front end wall portion 92. Accordingly, the tubular wall portion 94 includes an upper end wall portion 96a on an upper side, a lower end wall portion 96b on a lower side and left and right end wall portions 96c, 96b on both left and right sides. Further, a partition wall portion 98 extending in the front-rear direction is provided in a lateral center of the tubular wall portion 94, and an internal space of the shield shell 20 is partitioned into left and right accommodating tube portions 90a, 90b by this partition wall portion 98. A pair of accommodating portions 100, 100 open laterally outward are provided in a front end part of this partition wall portion 98, and these accommodating portions 100 communicate with internal spaces of the respective accommodating tube portions 90a, 90b. The spring member 26 is accommodated into each accommodating portion 100 as described later.

A front part of the upper end wall portion 96a of the shield shell 20 is formed with a through window 102 penetrating in a thickness direction (vertical direction), and a front part of each accommodating tube portion 90a, 90b and an outside space communicate with each other through the through window 102. The through window 102 has a substantially rectangular shape with round corners having a lateral dimension larger than a dimension in the front-rear direction, and each accommodating portion 100 provided in the partition wall portion 98 is open upward through this through window 102. Further, a substantially annular inner peripheral supporting portion 104 extending substantially over an entire periphery in a circumferential direction and a substantially annular outer peripheral receptacle 106 projecting upward on an outer peripheral side of the inner peripheral supporting portion 104 are integrally formed to the shield shell 20 on a peripheral edge part of the through window 102 in the upper end wall portion 96a of the shield shell 20.

An insulating cap 108 is assembled with the through window 102 in this shield shell 20. The insulating cap 108 has a substantially bottomed rectangular tube shape as a whole and is provided with a bottom plate portion 110 having a substantially rectangular shape with round corners, which is substantially the same shape as the through window 102, and a hollow cylindrical portion 112 projecting upward from an outer peripheral edge part of the bottom plate portion 110. Further, a substantially annular flange-like portion 114 projecting toward an outer peripheral side is integrally formed in an upper end part of the hollow cylindrical portion 112. In the assembled state of the shield connector 10, the bottom plate portion 110 is formed with substantially rectangular mating terminal insertion holes 116 at positions corresponding to the respective mating terminal insertion holes 62 in the respective housings 18a, 18b. In this way, the internal space (each mating terminal arrangement portion 28) in the terminal connecting portion 14a, 14b in each housing 18a, 18b communicates with the outside space through each mating terminal insertion hole 62 and each mating terminal insertion hole 116.

Note that a partitioning portion 118 laterally partitioning an internal space of the insulating cap 108 is provided in a lateral intermediate part of the insulating cap 108 and has a predetermined lateral dimension. This partitioning portion 118 overlaps the partition wall portion 98 of the shield shell 20 in the vertical direction when the insulating cap 108 is assembled with the shield shell 20. In this way, when the insulating cap 108 is assembled with the shield shell 20, the respective accommodating portions 100 provided in the partition wall portion 98 are covered from above by the partitioning portion 118. As a result, the respective spring members 26 accommodated in the respective accommodating portions 100 are hindered from coming out upward by the partitioning portion 118 and, in the first embodiment, a spring member cover portion is formed by this partitioning portion 118.

### (Spring Members 26)

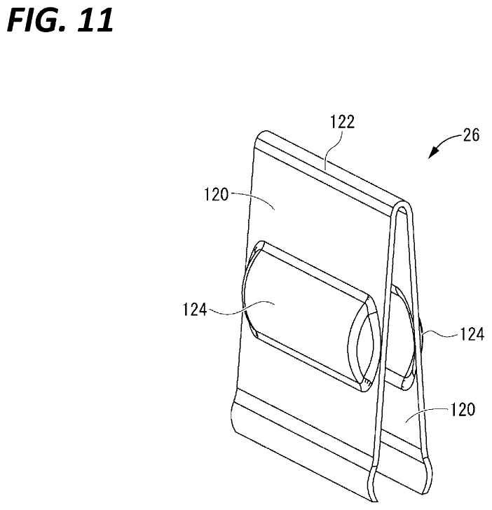

As also shown in FIG. 11, the spring member 26 is a leaf spring formed by bending a thin metal flat plate, and provided with a pair of flat plate-like portions 120, 120 and a folded portion 122 between these flat plate-like portions 120, 120. That is, the pair of flat plate-like portions 120, 120 are facing each other in the lateral direction in the assembled state of the shield connector 10, and the spring member 26 is resiliently deformable in directions to bring the respective flat plate-like portions 120 toward or away from each other by deforming the folded portion 122.

A pressing portion 124 projecting outward in a facing direction (outward in the lateral direction) is provided in an intermediate part of each flat plate-like portion 120. A lateral dimension between the projecting tips of the respective pressing portions 124 in a single state before being assembled as shown in FIG. 11 is larger than a lateral dimension between the bottom surface (left or right surface of the partition wall portion 98) of each accommodating portion 100 in the shield shell 20 and the lateral inner surface (surface on a side opposite to the surface where the contact ribs 84 project in the cover body 80 of each insulating cover 78) of each terminal side assembly 88a, 88b. In this way, when the spring member 26 is accommodated into each accommodating portion 100, the respective pressing portions 124 are pressed against the partition wall portion 98 and the insulating cover 78 and the respective flat plate-like portions 120 are resiliently deformed inward in the facing direction. A resilient restoring force due to this resilient deformation is applied to the partition wall portion 98 and the insulating cover 78, and each terminal side assembly 88a, 88b is biased in a direction separating from the partition wall portion 98.

### (Assembly Process of Shield Connector 10)

Next, a specific example of an assembly process of the shield connector 10 is described. Note that the assembly process of the shield connector 10 is not limited to that described below.

First, the metal flat plate having a specific shape and fixed to the terminal spring portions 48 is, for example, bent to form each terminal 16a, 16b including the terminal connecting portion 14a, 14b. Thereafter, each wire 38 is fixed to the wire connecting portion 40 in each terminal fitting 16a, 16b. Note that the waterproof rubber 46 is externally fit and mounted on the wire 38 at an arbitrary timing. The terminal fitting 16a, 16b fixed to the wire 38 is inserted into each housing body 49a, 49b, the heat dissipation member 22 is overlapped on the contact surface 35, which is the outer surface of the outer wall portion 32 constituting the terminal connecting portion 14a, 14b, from outside, and the holding member 68 is fixed to each housing body 49a, 49b from the outside of the heat dissipation member 22. Further, the insulating cover 78 is assembled with each housing body 49a, 49b. In this way, each terminal side assembly 88a, 88b is completed.

Thereafter, each terminal side assembly 88a, 88b is inserted through the rear opening of each accommodating tube portion 90a, 90b in the shield shell 20, and the waterproof rubber 46 is press-fit into the rear opening in each accommodating tube portion 90a, 90b. Subsequently, each spring member 26 is press-fit, inserted and accommodated into each accommodating portion 100 in the shield shell 20 through the through window 102 from above. Then, the flange-like portion 114 in the insulating cap 108 is overlapped on the inner peripheral supporting portion 104 in the shield shell 20 and the hollow cylindrical portion 112 is fit into the inner peripheral supporting portion 104. The insulating cap 108 is fixed to the inner peripheral supporting portion 104 by unillustrated convex-concave fitting or lock structure, whereby the through window 102 is covered by the insulating cap 108. In this way, the shield connector 10 of the first embodiment is completed.

In the shield connector 10 of the first embodiment manufactured as described above, the respective terminal side assemblies 88a, 88b are biased in the directions separating from the partition wall portion 98 by resilient restoring forces of the respective spring members 26 as described above, and the heat dissipation members 22 exposed on the outer surfaces of the respective terminal side assemblies 88a, 88b are pressed against the inner surfaces of the shield shell 20 located on outer sides (i.e. the inner surfaces of the right and left end wall portions 96d, 96c). Specifically, the resilient force of each spring member 26 is applied to each terminal fitting 16a, 16b (each terminal connecting portion 14a, 14b) via the insulating cover 78. The contact surface 35 of the terminal connecting portion 14a, 14b pressed by each spring member 26 is pressed into contact with the connecting portion side contact surface 70 of each heat dissipation member 22 and the shell side contact surface 72 of each heat dissipation member 22 pressed in this way is pressed against the inner surface of the shield shell 20 on the outer side.

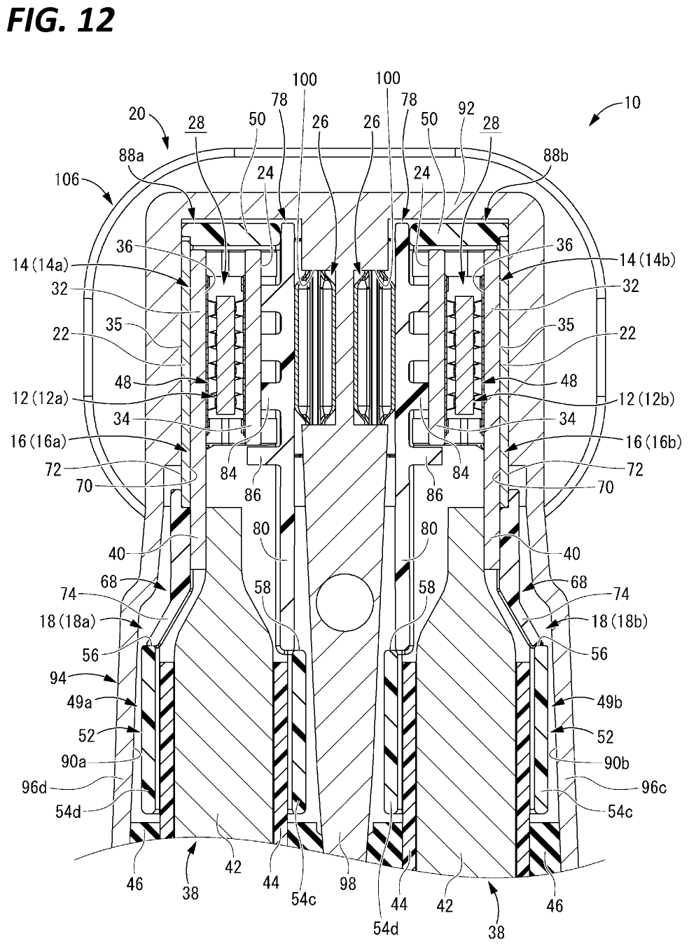

In this state, each mating terminal 12a, 12b is inserted from above through the mating terminal insertion hole 116 in the insulating cap 108, the mating terminal insertion hole 62 in each housing 18a, 18b and the upper opening 36 in each terminal connecting portion 14a, 14b. As shown in FIG. 12, the mating terminal 12a, 12b is arranged in the mating terminal arrangement portion 28 in each terminal connecting portion 14a, 14b. As a result, the respective terminal spring portions 48 are pressed between the mating terminal 12a, 12b and the terminal connecting portion 14a, 14b, and the mating terminal 12a, 12b and the terminal connecting portion 14a, 14b are more reliably conductively connected. Then, heat generated in association with energization between these mating terminal 12 and terminal connecting portion 14 is dissipated from the shield shell 20 to outside by way of the outer wall portion 32 in each terminal connecting portion 14a, 14b and the heat dissipation member 22.

Since the wire connecting portion 40 to be fixed to the core wire 42 of the wire 38 is provided in the rear end part of each terminal fitting 16a, 16b in the first embodiment, not only heat generated in a contact point portion of each terminal connecting portion 14a, 14b and each mating terminal 12a, 12b, but also heat generated in a connected part of each wire connecting portion 40 and each core wire 42 can be dissipated via each heat dissipation member 22. That is, since heat generated in the connected part of each wire connecting portion 40 and each core wire 42 where a relatively large amount of heat is generated is dissipated via each heat dissipation member 22 and the shield shell 20 in addition to heat generated between each terminal connecting portion 14a, 14b and the mating terminal 12, satisfactory heat dissipation is exhibited.

According to the shield connector 10 of the first embodiment structured as described above, each heat dissipation member 22 is provided in a heat dissipation path from the heat generating part due to energization between each terminal connecting portion 14a, 14b and each mating terminal 12a, 12b to outside via the shield shell 20, and each heat dissipation member 22 relatively low in thermal resistance (excellent in thermal conductivity) is adopted for each terminal connecting portion 14a, 14b instead of a resin member relatively high in thermal resistance. Thus, good heat dissipation is exhibited. Particularly, since the shield connector 10 of the first embodiment is not insert-molded like the conventional structure, but assembled, the formation of an air layer in a heat dissipation path due to the occurrence of short shots or voids is avoided and a reduction in heat dissipation performance is prevented. Further, there has been a possibility that a gap (air layer) is formed between members different in material due to a difference in linear expansion coefficient in the conventional structure, for example, if an ambient temperature largely changes, but each spring member 26 for pressing the heat dissipation member 22 against the terminal connecting portion 14a, 14b and pressing the heat dissipation member 22 against the shield shell 20 is provided with the mating terminal 12a, 12b arranged in each mating terminal arrangement portion 28 in the shield connector 10 of the first embodiment. In this way, even if the ambient temperature largely changes, the formation of gaps between each terminal connecting portion 14a, 14b and each heat dissipation member 22 and between each heat dissipation member 22 and the shield shell 20 is suppressed and a reduction in heat dissipation performance is prevented.

Further, each terminal connecting portion 14a, 14b easily getting hot due to heat generation associated with energization with each mating terminal 12a, 12b can be brought into contact with the shield shell 20 via each heat dissipation member 22 and a short heat dissipation path can be set. Thus, heat dissipation performance can be improved. Since an improvement in heat dissipation performance is achieved as described above, the shield shell 20 in charge of heat dissipation to outside can be reduced in size and, consequently, a size reduction of the entire shield connector 10 and a cost reduction by reducing the amount of a necessary material are achieved.

Each terminal connecting portion 14a, 14b has the rectangular tube shape, and the inside of each terminal connecting portion 14a, 14b is the mating terminal arrangement portion 28, into which each mating terminal 12a, 12b is inserted. Further, in the outer and inner wall portions 32, 34, which are the pair of facing wall portions in each terminal connecting portion 14a, 14b, the outer surface of the inner wall portion 34 is the pressure receiving surface 24 for receiving a resilient force of each spring member 26, and the outer surface of the outer wall portion 32 is the contact surface 35 to be held in contact with the connecting portion side contact surface 70 of each heat dissipation member 22. That is, the pressure receiving surface 24 and the contact surface 35 can be provided on the separate wall portions, and each surface 24, 35 can be formed to have a sufficiently large area. Therefore, heat generated in association with energization between each terminal connecting portion 14a, 14b and each mating terminal 12a, 12b can be more reliably transferred by each heat dissipation member 22 while the resilient force of each spring member 26 is more reliably received.

Further, since each terminal connecting portion 14a, 14b has the rectangular tube shape and the terminal spring portions 48 are provided inside the terminal connecting portion 14a, 14b, the deformation of the terminal spring portions 48 due to the contact of another member with the terminal spring portions 48 is avoided also when each terminal side assembly 88a, 88b and the shield connector 10 is manufactured by assembling each terminal connecting portion 14a, 14b, and a contact state of each terminal connecting portion 14a, 14b and each mating terminal 12a, 12b can be more reliably realized.

Each housing 18a, 18b (each housing body 49a, 49b) includes the second opening 58 for exposing the pressure receiving surface 24 of the terminal fitting 16a, 16b, and the insulating cover 78 is assembled with each second opening 58. In this way, even if each spring member 26 is made of metal as in the first embodiment, the resilient force of each spring member 26 can be applied to the pressure receiving surface 24 via the insulating cover 78 while insulation between each spring member 26 and each terminal connecting portion 14a, 14b is ensured.

Particularly, each insulating cover 78 is provided with the contact ribs 84, and the contact ribs 84 and the pressure receiving surface 24 come into contact when each terminal side assembly 88a, 88b is assembled. Since the plurality of (three in the first embodiment) contact ribs 84 are provided in each insulating cover 78, each contact rib 84 is formed to be relatively small and the influence of, for example, resin sinks and the like can be reduced. As a result, the respective contact ribs 84 and the pressure receiving surface 24 can be more reliably brought into contact, and the resilient force of each spring member 26 can be more reliably applied to the pressure receiving surface 24 in each terminal connecting portion 14a, 14b via each insulating cover 78.

Each insulating cover 78 includes the engaging rib 86 for hindering the terminal fitting 16a, 16b from coming out from the housing 18a, 18b by being engaged with the terminal connecting portion 14a, 14b. Specifically, in the assembled state of the shield connector 10, the inner wall portion 34 in each terminal connecting portion 14a, 14b and the engaging rib 86 are in contact or slightly separated, and each terminal fitting 16a, 16b can be hindered from coming out from the housing 18a, 18b by the inner wall portion 34 and the engaging protrusion 86 contacting and engaging each other also when an external force in the pull-out direction from the housing 18a, 18b is applied to the wire 38. In this way, the assembled state of the shield connector 10 can be stably maintained.

The holding member 68 for holding the heat dissipation member 22 is assembled with the first opening 56 in each housing 18a, 18b. That is, in the first embodiment, each terminal fitting 16a, 16b fixed to the wire 38, each housing body 49a, 49b, each heat dissipation member 22, each holding member 68 and each insulating cover 78 are assembled to configure each terminal side assembly 88a, 88b in assembling the shield connector 10. Thus, the detachment of each heat dissipation member 22 from the terminal side assembly 88a, 88b is prevented by providing the holding member 68 for holding the heat dissipation member 22. Therefore, it is possible not only to improve the manufacturing efficiency of each terminal side assembly 88a, 88b and consequently the shield connector 10, but also to stably maintain good heat dissipation of the shield connector 10.

The shield shell 20 is provided with the respective accommodating portions 100 for accommodating the respective spring members 26. In the first embodiment, since the respective accommodating portions 100 are provided in the partition wall portion 98 partitioning between the left and right accommodating tube portions 90a, 90b in the shield shell 20. Thus, the respective accommodating portions 100 can be provided with good space efficiency and the shield shell 20 and, consequently, the shield connector 10 can be reduced in size.

Particularly, each spring member 26 is inserted into each accommodating portion 100 through the through window 102 from above. The insulating cap 108 including the spring member cover portion (partitioning portion 118) is assembled with this through window 102. In this way, each spring member 26 is prevented from coming out from each accommodating portion 100. Further, the insulating cap 108 is provided with the mating terminal insertion holes 116. That is, parts enabling the insertion of the respective mating terminals 12a, 12b and parts preventing the respective spring members 26 from coming out are provided in the same member (insulating cap 108), and an increase in the number of components is avoided as compared to the case where these parts are provided in separate members.

### Second Embodiment

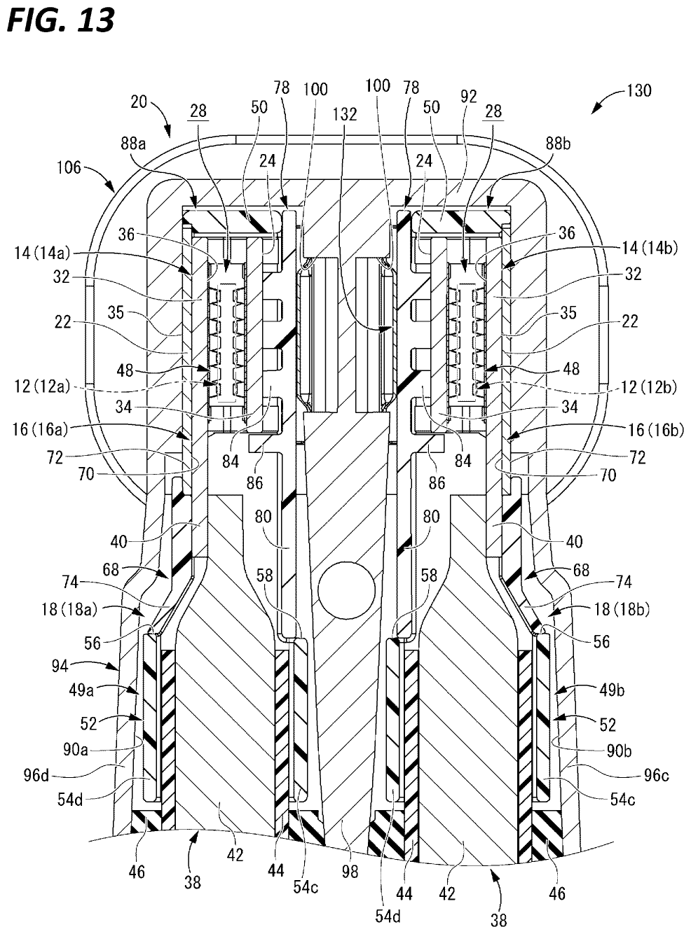

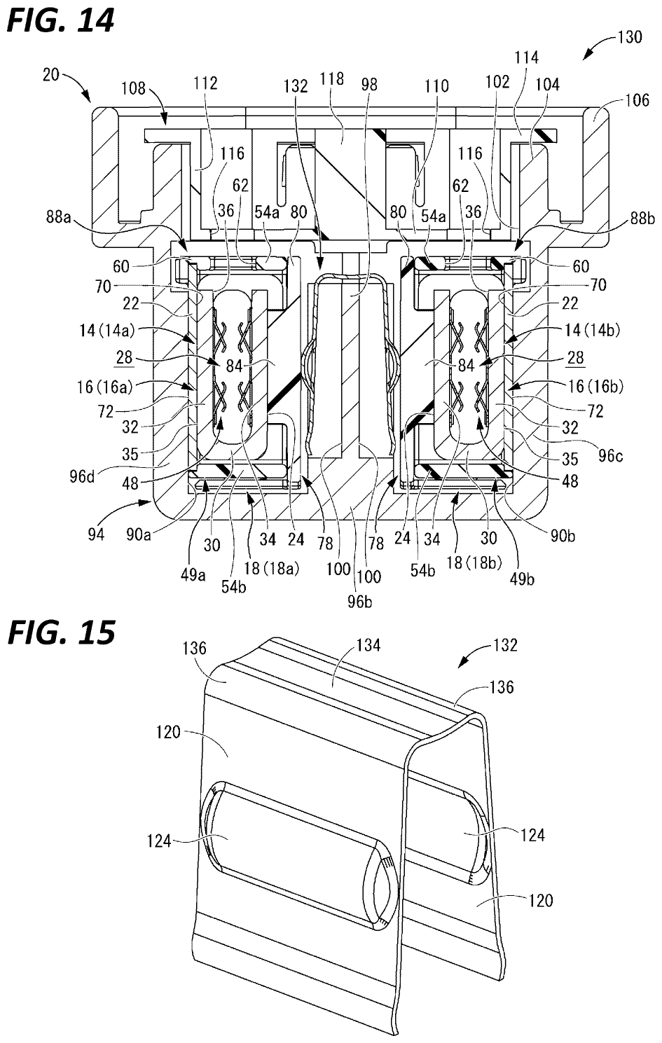

Next, a shield connector 130 of a second embodiment of the present disclosure is described with reference to FIGS. 13 to 15. Note that a basic structure of the shield connector 130 of the second embodiment is similar to that of the shield connector 10 of the first embodiment and differs only in the structure of a spring member 132. Note that, in the following description, substantially the same members and parts as those of the first embodiment are denoted by the same reference signs as in the first embodiment in figures and not described in detail.

That is, similarly to the shield connector 10 of the first embodiment, a pair of terminal fittings 16a, 16b are respectively accommodated in a pair of housings 18a, 18b and each of the housings 18a, 18b includes a heat dissipation member 22 in the shield connector 130 of the second embodiment. Further, pressure receiving surfaces 24 in terminal connecting portions 14a, 14b are arranged to face each other in terminal side assemblies 88a, 88b, and these terminal side assemblies 88a, 88b are covered by a single shield shell 20.

The pair of spring members 26, 26 are provided in the first embodiment, but the single spring member 132 is adopted here as shown in FIGS. 13 to 15. The structure of the spring member 132 is similar to the spring member 26 of the first embodiment and includes a pair of flat plate-like portions 120, 120 each having a pressing portion 124, and the upper ends of the respective flat plate-like portions 120 are coupled by a coupling portion 134 having a predetermined length (lateral dimension), instead of the folded portion 122. In this way, the respective flat plate-like portions 120 are resiliently deformable in directions toward or away from each other as bent portions 136 on both ends of the coupling portion 134 are deformed.

The spring member 132 shaped as just described is arranged over a part formed with accommodating portions 100 in a partition wall portion 98. That is, the respective flat plate-like portions 120 are inserted into the respective accommodating portions 100 and the coupling portion 134 is located above the partition wall portion 98. In the spring member 132 of the second embodiment, a lateral dimension between the projecting tips of the respective pressing portions 124 in a single state before being assembled is larger than a lateral dimension between the inner surfaces of the respective terminal side assemblies 88a, 88b laterally facing each other (surfaces of respective insulating covers 78 on sides opposite to surfaces where contact ribs 84 project in cover bodies 80 of the respective insulating covers 78) as shown in FIG. 15. In this way, when the spring member 132 is arranged by inserting the respective flat plate-like portions 120 into the respective accommodating portions 100, the respective pressing portions 124 are pressed against the respective insulating covers 78 on both left and right sides and the respective flat plate-like portions 120 are resiliently deformed inward in a facing direction. Then, a resilient restoring force due to this resilient deformation is applied to the respective insulating covers 78 and the respective terminal side assemblies 88a, 88b are biased in the directions away from each other.

In this way, the resilient force of the spring member 132 is applied to the respective pressure receiving surfaces 24 of the pair of terminal fittings 16a, 16b, the respective terminal connecting portions 14a, 14b are pressed against connecting portion side contact surfaces 70 of the respective heat dissipation members 22, and shell side contact surfaces 72 of the respective heat dissipation members 22 are pressed against the shield shell 20. As a result, also in the shield connector 130 of the second embodiment, effects similar to those of the shield connector 10 of the first embodiment can be exhibited. Particularly, since the single spring member 132 is adopted in the second embodiment, the number of components can be reduced and pressing forces against the respective heat dissipation members 22 via the respective left and right terminal connecting portions 14a, 14b can be made substantially equal, whereby a variation in heat dissipation performance can be suppressed. Further, an arrangement space for the spring member 132 can be reduced, for example, as compared to the case where the pair of spring members 26, 26 are provided as in the first embodiment, and the shield shell 20 and, consequently, the shield connector 130 can be reduced in size.

### Other Embodiments

The technique described in this specification is not limited by the above described and illustrated embodiments. For example, the following embodiments are also included in the technical scope of the technique described in this specification.
(1) Although the spring member 26 is a leaf spring formed by bending a thin metal flat plate in the above embodiment, there is no limitation to this. For example, a coil spring or the like may be used and disposed in an accommodating portion provided in the shield shell to apply a resilient force to the pressure receiving surface of the terminal fitting.
(2) Although a bipolar structure including two terminal fittings is adopted in the first embodiment, a monopolar structure or a structure with three or more poles may be adopted. Further, although the single spring member 132 is arranged between the terminals of the bipolar structure in the second embodiment, the structure only has to have two or more poles and a single spring member may be arranged between two terminals selected out of two or more terminals.
(3) Although the heat dissipation member 22 has a substantially flat plate shape and is made of ceramic in the above embodiments, there is no limitation to this if the heat dissipation member has an insulating property. The heat dissipation member can be, for example, made of synthetic resin having a larger thermal conductivity than air, besides ceramic, but the heat dissipation member preferably has a larger thermal conductivity than the synthetic resin constituting the housing (housing body). Specifically, silicone-based resins, non-silicone-based acrylic resins, ceramic-based resins and the like can be used. More particularly, a heat dissipation sheet, a heat dissipation gap filler, a thermally conductive grease, a thermally conductive silicone rubber and the like made of silicone-based resin can be used. Further, although the terminal connecting portions 14a, 14b are directly in contact with the heat dissipation members 22 and the heat dissipation members 22 are directly in contact with the shield shell 20 in the above embodiments, a heat dissipation sheet, a heat dissipation gap filler, a thermally conductive grease or the like as described above may be interposed between these members.
(4) The shapes of the housing and the shield shell are not limited. In the housing, the insulating cover and the holding member are not essential. Further, the outer peripheral receptacle is not essential in the shield shell and the shape of the insulating cap is also not limited.

### LIST OF REFERENCE NUMERALS

10 shield connector (first embodiment)
12, 12a, 12b mating terminal
14, 14a, 14b terminal connecting portion
16, 16a, 16b terminal fitting
18, 18a, 18b housing
20 shield shell
22 heat dissipation member
24 pressure receiving surface
26 spring member
28 mating terminal arrangement portion
30 lower wall portion
32 outer wall portion (facing wall portion)
34 inner wall portion (facing wall portion)
35 contact surface
36 upper opening
38 wire
40 wire connecting portion
42 core wire
44 insulation coating
46 waterproof rubber
48 terminal spring portion
49a, 49b housing body
50 front wall portion
52 peripheral wall portion
54a upper wall portion
54b lower wall portion
54c left wall portion
54d right wall portion
56 first opening
58 second opening
60 positioning protrusion
62 mating terminal insertion hole
64 insulating cover engaging protrusion
66 holding member engaging protrusion
68 holding member
70 connecting portion side contact surface
72 shell side contact surface
74 holding member body
76 engaging frame body
78 insulating cover
80 cover body
82 engaging frame body
84 contact rib
86 engaging rib
88a, 88b terminal side assembly
90a, 90b accommodating tube portion
92 front end wall portion
94 tubular wall portion
96a upper end wall portion
96b lower end wall portion
96c left end wall portion
96d right end wall portion
98 partition wall portion
100 accommodating portion
102 through window
104 inner peripheral supporting portion
106 outer peripheral receptacle
108 insulating cap
110 bottom plate portion
112 hollow cylindrical portion
114 flange-like portion
116 mating terminal insertion hole
118 partitioning portion (spring member cover portion)
120 flat plate-like portion
122 folded portion
124 pressing portion
130 shield connector (second embodiment)
132 spring member
134 coupling portion
136 bent portion

1. A shield connector, comprising:
a terminal fitting including a terminal connecting portion to be connected to a mating terminal;
an insulating housing for accommodating the terminal fitting;
a shield shell for covering an outer surface of the housing;
an insulating heat dissipation member having a connecting portion side contact surface to be held in contact with the terminal connecting portion and a shell side contact surface to be held in contact with the shield shell by being exposed through a first opening of the housing; and
a spring member for applying a resilient force to a pressure receiving surface of the terminal fitting,
the terminal connecting portion being pressed against the connecting portion side contact surface of the heat dissipation member and the shell side contact surface of the heat dissipation member being pressed against the shield shell by the resilient force of the spring member applied to the pressure receiving surface of the terminal fitting.

2. The shield connector of claim 1, wherein:
the terminal connecting portion of the terminal fitting has a rectangular tube shape,
a mating terminal arrangement portion is formed inside the terminal connecting portion, the mating terminal being inserted into the mating terminal arrangement portion, and
the pressure receiving surface is formed by one of a pair of facing wall portions of the terminal connecting portion, a contact surface is formed by the other of the pair of facing wall portions, and the contact surface is pressed into contact with the connecting portion side contact surface of the heat dissipation member.

3. The shield connector of claim 1, wherein:
the housing includes a second opening for exposing the pressure receiving surface of the terminal fitting and an insulating cover to be assembled with the second opening to contact the pressure receiving surface, and
the spring member applies the resilient force to the pressure receiving surface via the insulating cover.

4. The shield connector of claim 3, wherein the insulating cover includes a flat plate-like cover body for covering the second opening and a plurality of contact ribs projecting from the cover body toward the pressure receiving surface to be held in contact with the pressure receiving surface.

5. The shield connector of claim 3, wherein the insulating cover includes an engaging rib for hindering the terminal fitting from coming out from the housing by being engaged with the terminal connecting portion.

6. The shield connector of claim 1, wherein the housing includes a holding member for holding the heat dissipation member by being assembled with the first opening.

7. The shield connector of claim 1, wherein:
a pair of the housings for respectively accommodating a pair of the terminal fittings includes each the heat dissipation member and are covered by the single shield shell with the respective pressure receiving surfaces arranged to face each other,
the single spring member is arranged between the pair of housings, and
the resilient force of the spring member is applied to the pressure receiving surface of each of the pair of terminal fittings, each terminal connecting portion is pressed against the connecting portion side contact surface of each heat dissipation member, and the shell side contact surface of each heat dissipation member is pressed against the shield shell.

8. The shield connector of claim 1, wherein the shield shell includes an accommodating portion for accommodating the spring member.

9. The shield connector of claim 8, comprising an insulating cap to be assembled with the shield shell while covering the accommodating portion of the shield shell, wherein:
the insulating cap integrally includes a mating terminal insertion hole and a spring member cover portion.
